(19) United States
(12) Patent Application Publication
(10) Pub. No.: US 2017/0318673 A1
(43) Pub. Date: Nov. 2, 2017

(54) CONNECTOR FOR PRINTED CIRCUIT BOARD

(71) Applicant: Arista Networks, Inc., Santa Clara, CA (US)

(72) Inventor: Warren Meggitt, Santa Clara, CA (US)

(21) Appl. No.: 15/143,376

(22) Filed: Apr. 29, 2016

(51) Int. Cl. H05K 1/11; H05K 3/40; H05K 3/00

(52) U.S. Cl. CPC H05K 1/115; H05K 3/0047; H05K 3/4038

(57) ABSTRACT

A printed circuit board is provided. The board includes a plurality of vias through the printed circuit board, each having a first section with a first width, a second section with a second width less than the first width, and a third section with a third width greater than the second width and less than the first width. The second section is located between the first section and the third section, the first and second sections are plated, and the third section lacks plating. At least one of the plurality of vias has the first width dimensioned to receive a connector pin inserted through the first face. A further at least one of the plurality of vias has the first width dimensioned to receive a further connector pin inserted through the second face. Further versions of the printed circuit board and method of making a printed circuit board are provided.

### BACKGROUND

Connectors with high densities of pins, mated to printed circuit boards, are well-known in many types of electronic devices, including network devices. When it is desired to increase the number of connectors mounting to a printed circuit board, for example to increase the number of channels in a network device, problems arise. Board size could increase, if all of the connectors are on the same side of the printed circuit board, but the board will no longer fit the desired form factor for packaging and rack mounting. Signal travel could be over differing distances and necessitate buffering, amplification or other circuitry to compensate for circuit path differences and signal quality differences. Solving these problems by mounting connectors on both faces of the printed circuit board for more symmetric signal trace lengths may introduce more problems. Connector pins could collide and bend, some vias and via pads could electrically short to other vias. Signal crosstalk and ground noise could increase because of newly introduced spacing problems and signal couplings. High-speed signals could have signal integrity problems that need different solutions from what works for low-speed signals. Various pins, be they signal, power supply or ground, could be misaligned from one face of the printed circuit board to the other face, especially if the connectors were not originally designed for mounting on both sides of a a printed circuit board (called a Belly-to-Belly mount). Hypothetically ideal solutions might not be practical with existing printed circuit board manufacturing techniques. And, redesigning the connectors and manufacturing all of the variations of the connectors that currently exist within a connector family that conforms to an existing standard is time-consuming and costly, perhaps prohibitively so for a product or product line. Given the challenges described above, there is a need in the art for a solution.

### SUMMARY

In some embodiments, a printed circuit board with a first face and opposing second face is provided. The printed circuit board includes a plurality of vias through the printed circuit board, each having a first section with a first width, a second section with a second width less than the first width, and a third section with a third width greater than the second width and less than the first width. The second section is located between the first section and the third section, the first and second sections are plated, and the third section lacks plating. At least one of the plurality of vias has the first width dimensioned to receive a connector pin inserted through the first face into the first section. A further at least one of the plurality of vias has the first width dimensioned to receive a further connector pin inserted through the second face into the first section.

In some embodiments, a printed circuit board with a first face and opposing second face is provided. The printed circuit board includes a plurality of vias in the printed circuit board, each having plating extending from a face of the printed circuit board to less than entirely through the printed circuit board. A first one of the plurality of vias is arranged to receive a first connector pin through the first face of the printed circuit board. A second one of the plurality of vias is arranged to receive a second connector pin through the second face of the printed circuit board. A plated ground via extends to the first face and the second face, the plated ground via adjacent to the first one and the second one of the plurality of vias.

In some embodiments, a printed circuit board with a first face and opposing second face is provided. The printed circuit board includes a plurality of staggered vias, extending through the printed circuit board, and having a first section staggered relative to a second section. Each of the plurality of staggered vias is dimensioned to receive a first pin from a first connector, through the first face of the printed circuit board. Each of the plurality of staggered vias is dimensioned to receive a second pin from a second connector, through the second face of the printed circuit board.

In some embodiments, a method for making a printed circuit board is provided. The method includes drilling, to a first diameter, one or more holes through a printed circuit board. The method includes back drilling, to a second diameter greater than the first diameter, each of the one or more holes from a first face of the printed circuit board to a first depth, wherein the second diameter and the first depth are dimensioned so that each of the one or more holes can receive a connector pin. The method includes plating the one or more holes and further back drilling, to a third diameter greater than the first diameter and less than the second diameter, each of the one or more holes from a second, opposed face of the printed circuit board to a second depth so as to remove the plating to the second depth.

Other aspects and advantages of the embodiments will become apparent from the following detailed description taken in conjunction with the accompanying drawings which illustrate, by way of example, the principles of the described embodiments.

### BRIEF DESCRIPTION OF THE DRAWINGS

The described embodiments and the advantages thereof may best be understood by reference to the following description taken in conjunction with the accompanying drawings. These drawings in no way limit any changes in form and detail that may be made to the described embodiments by one skilled in the art without departing from the spirit and scope of the described embodiments.

FIG. 1A is a perspective view of a printed circuit board with both faces receiving connectors in groups.

FIG. 1B is a perspective view of a variation of the printed circuit board and the groups of connectors of FIG. 1A.

FIG. 2 is a cross-section view of the printed circuit board, showing connector pins inserted into a via.

FIG. 3 is a cross-section view of the printed circuit board, showing connector pins inserted into dual-diameter vias, which support closer spacing of vias.

FIG. 4 is a cross-section view of the printed circuit board, showing back drilled dual-diameter vias, with plating removed from a portion of the via so as to reduce crosstalk with neighboring vias, especially those oriented in an opposite direction.

FIG. 5A is a top projected view that depicts a problem with ground vias colliding with vias for signal pins, creating a short-circuit.

FIG. 5B is a top projected view that depicts a solution to the problem of FIG. 5A, with a solitary or singular ground via adjacent to two signal vias.

FIG. 6 depicts the via arrangement of FIG. 5B in a lateral projected cross-section view, showing ground return paths through the solitary or singular ground via for two signals with pins on opposed faces of the printed circuit board.

FIG. 7A depicts offset back drilling in the printed circuit board.

FIG. 7B is a cross-section view of the printed circuit board, showing a staggered via produced by the offset back drilling of FIG. 7A.

FIG. 7C is a cross-section view of the printed circuit board, showing a variation of the staggered via of FIG. 7B.

FIG. 7D is a cross-section view of the printed circuit board, showing a further variation of the staggered via of FIG. 7B.

FIG. 8 is a perspective view of a QSFP (quad small form factor pluggable) connector, suitable for use in embodiments of the present disclosure, with the connector pins shown.

FIG. 9 is a flow diagram of a method for making a printed circuit board, which can produce the embodiments shown in FIGS. 4 and 6 and variations thereof.

### DETAILED DESCRIPTION

Various embodiments of printed circuit boards, vias, drilling and other printed circuit board manufacturing techniques disclosed herein can be used in various combinations for making and using printed circuit boards that can mount press-fit connectors on both faces of the printed circuit board. Each embodiment or variation thereof solves one or more problems and is therefore applicable to solving similar problems in other connector and printed circuit board arrangements, and is not limited to the specific connector shapes and printed circuit boards depicted herein. The drawings are representative and suggestive of geometries in various embodiments but are not to scale. Descriptions herein should be interpreted as gravity independent, in that a printed circuit board and connectors may be mounted in various orientations and a description of “top”, “bottom”, “upper”, “lower”, etc., is given as relative to a drawing, not absolute as to an orientation of a component in a manufacturing or operating environment. Variations of the vias with a greater number or lesser number of sections, and different shapes for the sections, are readily devised in keeping with the teachings herein.

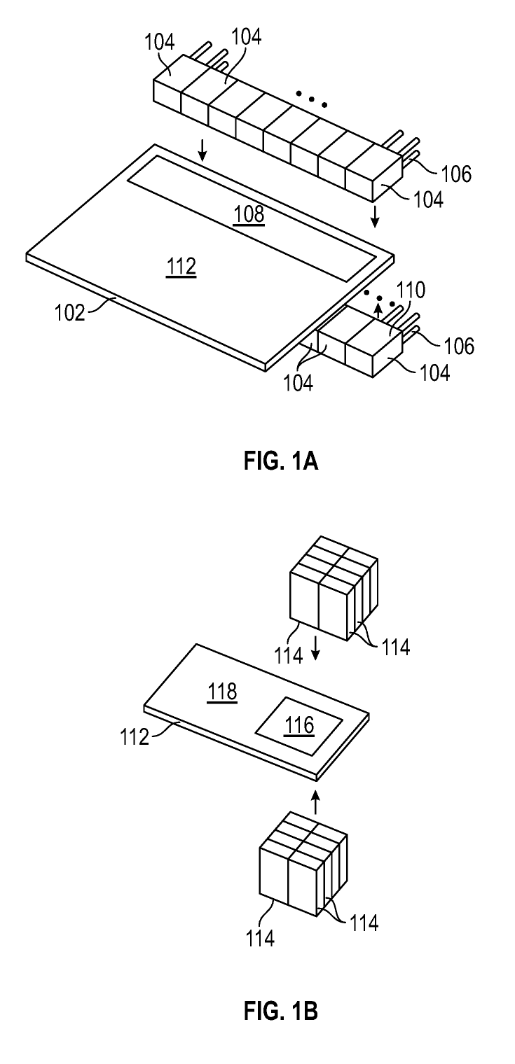

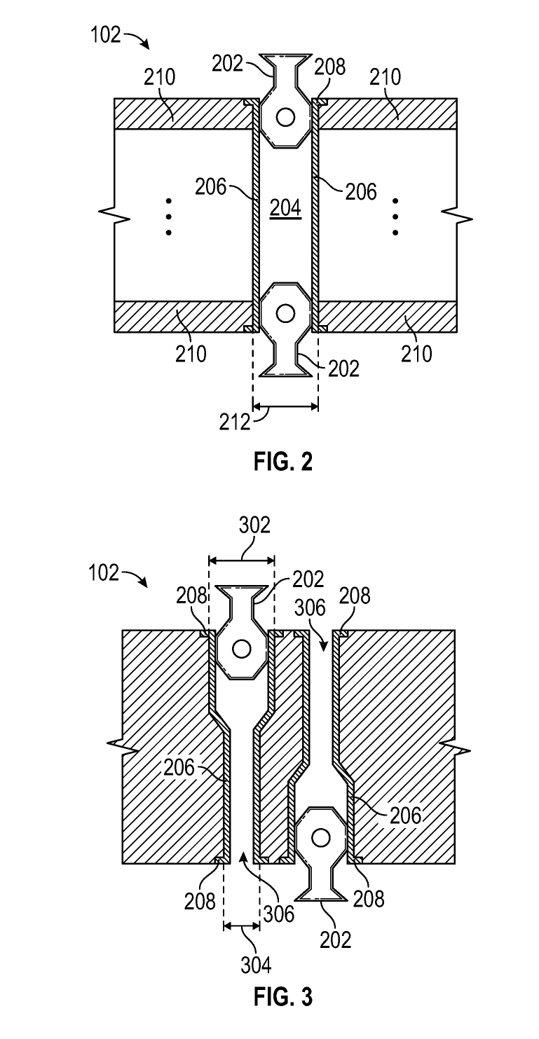

FIG. 1A is a perspective view of a printed circuit board 102 with both faces receiving connectors 104 in groups. This can be called a belly-to-belly arrangement of connectors 104. In this depiction, the connectors 104 are arranged eight in a row in each group. One group of connectors 104 is shown above and descending towards one face of the printed circuit board 102, the other group is shown below and ascending towards an opposing face of the printed circuit board 102. Cables 106 attach to the connectors 104, for routing signals through the cables 106, through the connectors 104, and to and from the circuit traces in the printed circuit board 102. In one embodiment, each connector 104 has four cables, corresponding to four channels for a network device, so that each group of eight connectors 104 has 32 channels, and the printed circuit board 102 has 64 channels. Power and ground connections are also achieved through the cables 106, and connectors 104, to the printed circuit board 102. Each connector 104 has a pin face 110, with a plurality of pins (not shown in FIG. 1A, but see FIGS. 2-4, 6, 7B and 8), that connects to a pin receiving area 108 of the face of the printed circuit board 102 to which that connector 104 mounts. Each of the two opposed faces of the printed circuit board 102 has a pin receiving area 108, details of which are shown in FIGS. 2-8 as problem solutions. A circuitry area 112 has integrated circuits, or, on an unpopulated board, is available for integrated circuits, although various embodiments of the printed circuit board 102 are further applicable to signal routing boards that do not have integrated circuits thereupon.

FIG. 1B is a perspective view of a variation of the printed circuit board 102 and the groups of connectors 104 of FIG. 1A. Here, the connectors 114 are organized as a pair of 2×4 groups of eight connectors 114, for a total of eight connectors 114 above and eight connectors 114 below the printed circuit board 112. The pin receiving area 116 of each face of the printed circuit board 112 is arranged accordingly. A circuitry area 118 has or is available for integrated circuits 112. Other printed circuit boards and arrangements and numbers of connectors are readily devised in keeping with the teachings herein.

FIG. 2 is a cross-section view of the printed circuit board 102, showing connector pins 202 inserted into a via 204. The particular connector pins 202 depicted are pressfit pins, which have void (depicted as the central oval) and collapse slightly upon insertion into a via 204, but other types of pins could be used. Generally, vias 204 that receive pins 202 are dimensioned to grip the pins 202, for good mechanical and electrical contact, and to retain the connector. Plating 206 on the wall(s) of the via 204 provide electrical connectivity to the pins 202 and ground planes 210, or power planes or signal traces, etc., depending upon what electrical connections and definitions the pins 202 have. Standard printed circuit board manufacturing techniques such as drilling with drill bit(s) or laser(s), etching, lamination, and plating are used to produce the via 204, which extends to both faces of the printed circuit board 102 and is plated all the way through from one face to the other. Width 212 of the via is constant and uniform throughout the via 204, and should be dimensioned to receive the pins 202. This embodiment is suitable for pins 202 that are in mutual alignment as inserted through opposed faces of the printed circuit board 102. This has applicability for ground pins (shown), and also power pins and signal pins in various embodiments.

FIG. 3 is a cross-section view of the printed circuit board 102, showing connector pins 202 inserted into dual-diameter vias 306, which support closer spacing of vias. For comparison, constant-width vias 204 such as depicted in FIG. 2 have a greater minimum spacing requirement, for a given pin 202 size, than dual-diameter vias 306 oriented in opposing directions as depicted in FIG. 3. This is because the narrower portion of the dual-diameter via 306 has a smaller pad 208 than does the wider portion of the dual-diameter via 306, so, for a minimum pad spacing dimension, the opposed dual-diameter vias 306 are spaced closer together than the constant-width vias 204.

The dual-diameter via 306 can be formed by making a hole of a first, smaller diameter 304 (e.g., with a smaller drill bit or finer laser beam) all the way through the printed circuit board 102, then back drilling to a larger diameter 302 (e.g., with a larger drill bit or laser beam), to a controlled depth. This is followed by plating the entire via 306, so that there is plating 206 on the wall(s) of the dual-diameter via 306, from one face of the printed circuit board 102 to the opposing face. Circuit trace(s) in various layers in the printed circuit board 102 (even including a top or bottom layer) are readily made to the plating 206 at the thicker or thinner or transitioning portions of the dual-diameter via 306, or even at a surface of the printed circuit board 102. The larger diameter 302 should be dimensioned to receive the pin 202. The smaller diameter 304 could be dimensioned to be a minimum in accordance with printed circuit board manufacturing capabilities. In some embodiments, the dual-diameter via 306 is suitable for lower speed signals, e.g., of 1 MHz or below. Because of the closer spacing afforded by the dual-diameter vias 306, as compared to single-diameter vias (see FIG. 2), the dual-diameter vias 306 can be used to solve crowding or spacing problems arising from using connectors 104 on both faces of a printed circuit board 102.

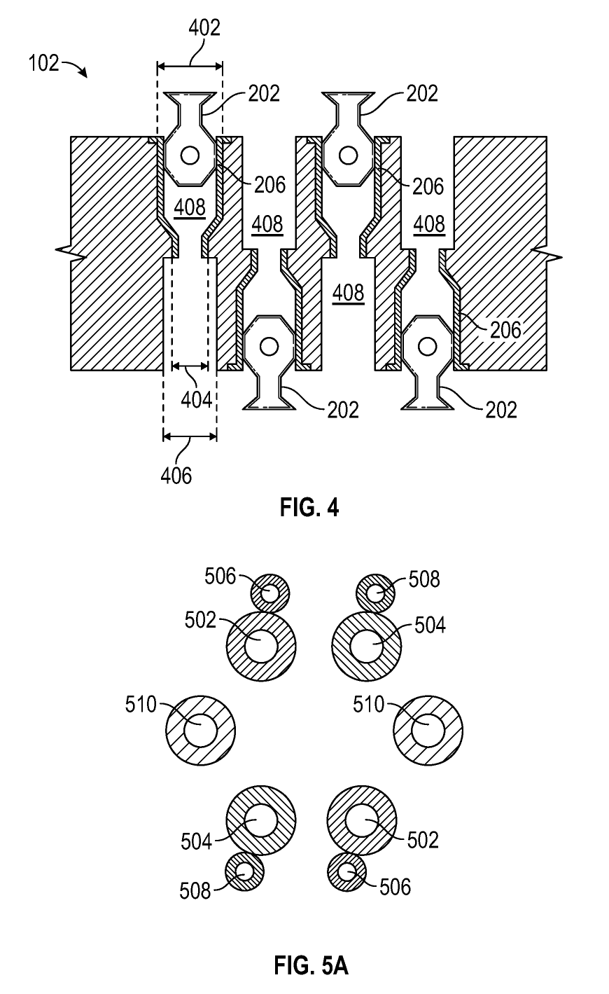

FIG. 4 is a cross-section view of the printed circuit board 102, showing back drilled dual-diameter vias 408, with plating 206 removed from a portion of the via so as to reduce crosstalk with neighboring vias, especially those oriented in an opposite direction. Each back drilled dual-diameter via 408 can be produced by starting with a dual-diameter via 306 as shown in FIG. 3, e.g., produced from a first hole by a first back drilling followed by plating. This is followed by a second back drilling to a controlled depth from the face of the printed circuit board 102 opposed to the face from which the pin 202 is received into that via 408. A second back drilling removes the plating 206 from the first back drilled portion of the via 408, to the controlled depth of the second back drilling. This results in a via 408 that has three diameters. A first section having a wider diameter 402 is produced by the first back drilling and dimensioned to receive the pin 202 through a face of the printed circuit board 102. A second, internal section having a narrower diameter 404 is produced by the first drilling, prior to any of the back drilling, and can be a minimum manufacturing diameter or other relatively narrow diameter. Plating 206 is added after the drillings produce the first and second diameters 402, 404. Preferably, a narrower second diameter 404 for that corresponding necked-down second section of the via 408 results in less total area of plating 604 in that second section of the via 408 and less radiation of electromagnetic energy arising from signal activity, also less antenna size susceptible to crosstalk. A third section having a third diameter 406 open to the opposing face of the printed circuit board 102 is produced by the second back drilling, which removes the plating. It is preferred that the third diameter 406 be slightly greater than the second diameter 404, and less than the first diameter 402, so as not to limit via spacing, but the third diameter 406 could be greater than or equal to the first diameter 402 in further embodiments.

Signal connections can be made from the via 408 to one or more conducting layers in the printed circuit board 102. For example, signal traces could be on a surface layer connected to a pad 208 of the via 408, or on an internal layer (see, e.g., FIG. 2). A signal trace on an internal layer could connect to the via 408 at the plating 206, i.e., anywhere along the thicker or thinner sections of the via 408 that have plating 206, wherever a signal layer is defined in the printed circuit board 102. Generally, one of these vias 408 connects to a signal trace on a layer on the same half of the printed circuit board 102, relative to the depth of the via 408, as the face of the printed circuit board 102 through which that via receives the connector pin 202. In other words, a via 408 that receives a signal pin 202 through an upper face of the printed circuit board 102 generally connects that signal to a signal trace on the upper half of the thickness of the printed circuit board 102. This is because the plating 206 has been removed from the lower half or other portion of the via 408, and plating 206 extends halfway through or in any case less than all the way through the printed circuit board 102 from the upper face. A via 408 that receives a signal pin 202 through a lower face of the printed circuit board generally connects that signal to a signal trace on the lower half of the thickness of the printed circuit board 102. This is because the plating 206 has been removed from the upper half or other portion of the via 408 and extends halfway through or in any case less than all the way through the printed circuit board 102 from the lower face.

When a back drilled dual-diameter via 408 is arranged adjacent to another back drilled dual-diameter via 108 in an opposed orientation, so that the first via 408 receives a pin 202 through one face of the printed circuit board 102 and the second via 408 receives another pin 202 through the opposed face of the printed circuit board 102, signal crosstalk between the two vias 408 is minimized. This compares favorably with crosstalk that would have occurred if the plating in both vias 408 had been left intact, as is the case shown in FIG. 3. Thus, embodiments depicted in FIG. 4 are suitable for higher speed signals, e.g., in the gigahertz range and up. Because of both spacing advantages and advantages in crosstalk reduction, the back drilled dual-diameter vias 408 can be used to solve both spacing and crowding problems, and crosstalk problems arising from having signals entering or exiting both faces of a printed circuit board 102 to connectors 104. In order to minimize signal crosstalk, it is preferred that the second back drilling, the one that removes the plating and produces the third diameter 406, have controlled depth greater than or equal to the first controlled depth, greater than or equal to the extent of the plating 206 in a neighboring, oppositely oriented via, or greater than or equal to halfway through the printed circuit board 102. However, lesser amounts of plating removal due to a shallower second controlled depth will reduce crosstalk, too.

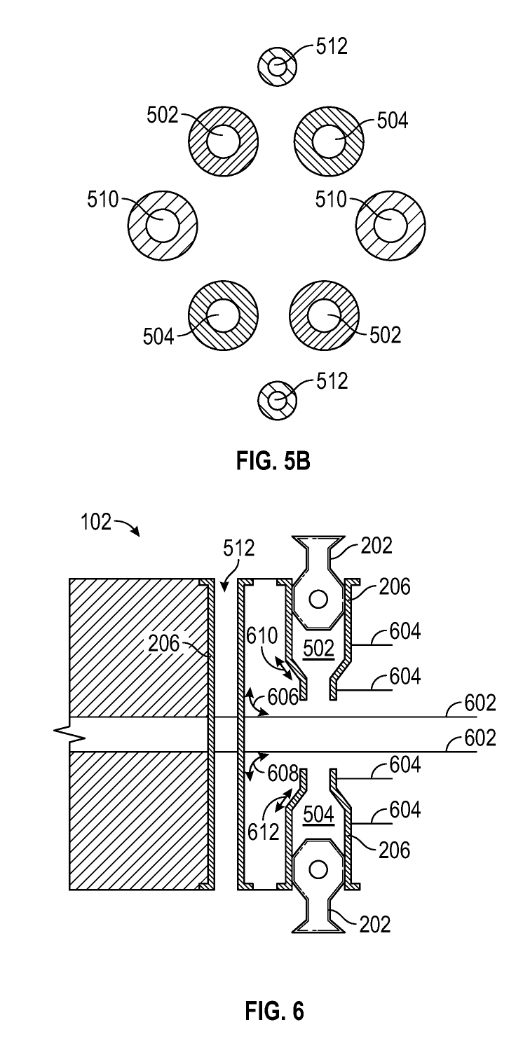

FIG. 5A is a top projected view that depicts a problem on a printed circuit board design with ground vias 506 colliding with vias 502, 504 for signal pins, creating a short-circuit. For example, such a problem could arise when a connector 104 was originally designed for use on one face of a printed circuit board, and it is desired to use the connector 104 on both opposed faces of the printed circuit board 102. In the example shown, two of the vias 502 are for pins 202 (not shown in FIG. 5A, but see FIG. 2) carrying a differential pair transmitter signal, and these pins 202 are to be inserted through the top face of the printed circuit board 102. The original design for single-sided mounting of the connector 104 to the printed circuit board called for two ground vias 508 through the printed circuit board, to accompany and provide ground return paths for signal activity on the differential pair transmitter signal carried through the vias 502. Two more of the vias 504 are for pins 202 carrying a differential pair receiver signal, and these pins 202 are to be inserted through the bottom face of the printed circuit board 102. The original design for single-sided mounting of the connector 104 to the printed circuit board called for two ground vias 506, to accompany and provide ground return paths for signal activity on the differential pair receiver signal carried through the vias 504. Combining these requirements leads to the short-circuit problem between ground vias 506 and signal vias 502, and between ground vias 508 and signal vias 504. Ground pin vias 510, for ground pins of the connectors 104, do not interfere, and are acceptable as-is in the design.

FIG. 5B is a top projected view that depicts a solution to the problem of FIG. 5A, with a solitary or singular ground via 512 adjacent to two signal vias 502, 504. This arrangement is repeated with another solitary or singular ground via 512 adjacent to the two other signal vias 502, 504. It is readily discerned that the placement of the solitary or singular ground via 512 solves the spacing issues, so that there is no short-circuit as in FIG. 5A. What is not so visible is how the solitary or singular ground via 512 works to provide a ground return path for each of the two signals, which is shown in FIG. 6. In one embodiment, the signal vias 502 for the differential pair transmit (TX) pins 206 (see FIG. 6) have the transmit pins 206 inserted from the top face of the printed circuit board 102, and the signal vias 504 for the differential pair receive (RX) pins 206 (see FIG. 6) inserted from the bottom face of the printed circuit board 102.

FIG. 6 depicts the via arrangement of FIG. 5B in a lateral projected cross-section view, showing ground return paths through the solitary or singular ground via 512 for two signals with pins 202 on opposed faces of the printed circuit board 102. Details of the back drilling to produce the signal vias 502, 504 (see, e.g., FIG. 4) are omitted so that the projected view of FIG. 6 can be shown without interfering lines in the drawing. That is, per FIG. 5B, the signal via 502 for one of the transmit signal pins 206 has the pin 206 inserted into the via 502 from the top face of the printed circuit board 102, and the signal via 504 for one of the received signal pins 206 has the pin 206 inserted into the via 504 from the bottom face of the printed circuit board 102. The solitary ground via 512 is immediately adjacent to these signal vias 502, 504. Again per FIG. 5B, the solitary ground via 512 and the two signal vias 502, 504 are not actually coplanar, although they appear so due to the projected cross-section view of FIG. 6. In a further embodiment, the solitary ground via 512 and the two signal vias 502, 504 could be coplanar, with the signal vias 502, 504 as blind vias that connect an internal layer(s) to an outer layer but do not go all the way through the printed circuit board 102. Each such blind via could be produced with two controlled depth drillings and plating, without the back drilling, or by drilling in the layers of the printed circuit board 102 prior to lamination, in various embodiments.

The singular or solitary ground via 512 is plated throughout, with plating 206 extending to both faces of the printed circuit board 102. In some embodiments, the singular or solitary ground via 512 has no mechanical connection to any connector pin, and can be a minimum width via.

Signal current 610 from signal activity on the transmit pin 202 travels back and forth in the plating 206 on the transmit pin signal via 502. This signal current 610 induces a ground return current 606 in an upper portion of the solitary or singular ground via 512 and a portion of the upper ground plane 602, to which the singular or solitary ground via 512 is connected. Similarly, signal current 612 from signal activity on the receive pin 202 travels back and forth in the plating 206 on the receive pin signal via 504. This signal current 612 induces a ground return current 608 in a lower portion of the solitary or singular ground via 512 and a portion of the lower ground plane 602, to which the singular or solitary ground via 512 is also connected. The solitary or singular ground via 512 thus serves to produce ground return currents 606, 608 for both of the adjacent signal vias 502, 504. There is thus no requirement, in this arrangement, that each signal via should have its own ground via, which would result in there being two ground vias for the two signal vias 502, 504.

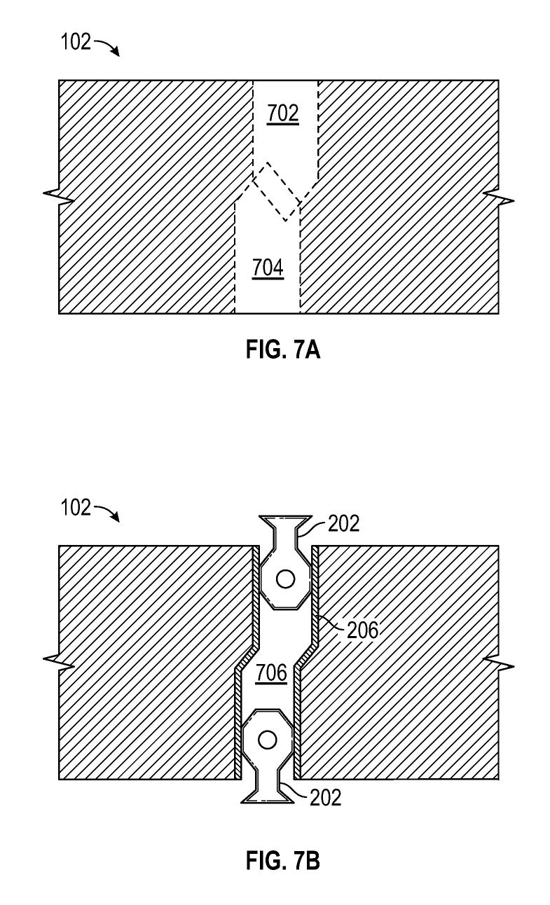

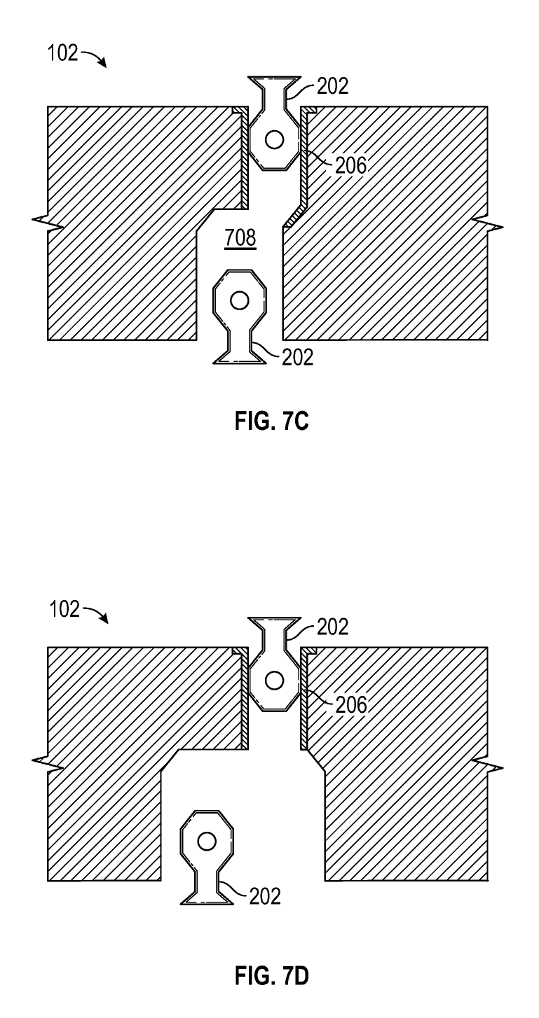

FIG. 7A depicts offset back drilling in the printed circuit board 102. In a process for back drilling, the first drilling 702 (depicted in dashed outline) is to a first controlled depth from one face of the printed circuit board 102. The second drilling 704, offset from the first drilling 702, is to a second controlled depth from a second opposed face of the printed circuit board 102. The two drillings 702, 704 should be arranged so that there is overlap at the controlled depth of each drilling 702, 704, and so that the passages meet in the center or at least in the interior of the printed circuit board 102. The two controlled depths are not required to be identical, although when they are, this produces a symmetric depth offset back drilling. This process is followed by plating the resultant via. No pilot hole, through the entire thickness of the printed circuit board 102 (e.g., an initial, straight through hole), is required prior to the two controlled depth back drillings. Generally, each drilling 702, 704 should use a greater than minimum diameter for a given printed circuit board manufacturing process, as it would be difficult to make minimum diameter controlled depth holes meet.

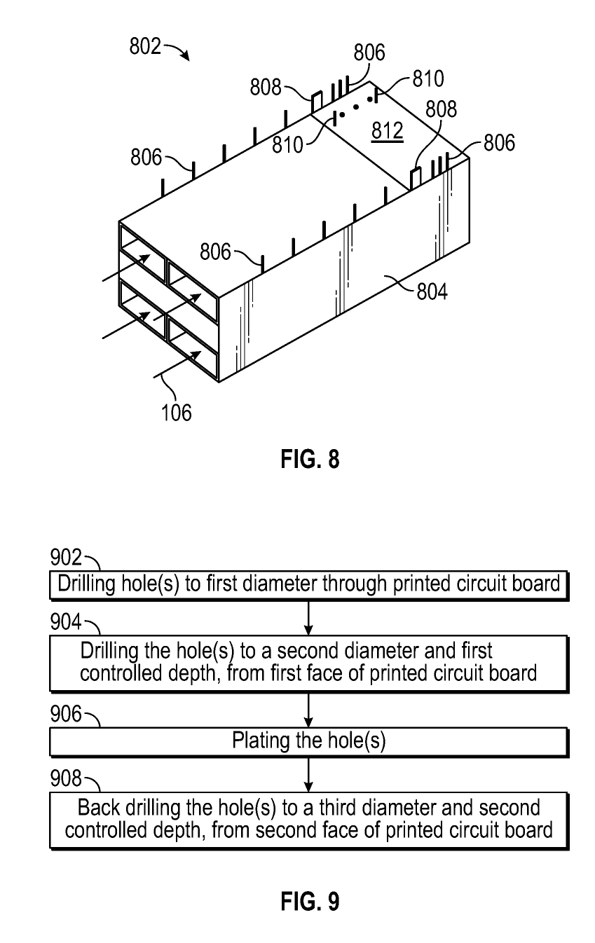

FIG. 7B is a cross-section view of the printed circuit board, showing a staggered via 706 produced by the offset back drilling of FIG. 7A. Offsetting one drilling 704 with respect to the other drilling 702 (as shown in FIG. 7A) results in the first section of the via 706 being staggered relative to the second section of the via 706. The stagger or offset in the walls of the via 706, from one face of the printed circuit board 102 relative to the other, opposed face of the printed circuit board 102, make the staggered via 706 suitable for offset pins 202 inserted from opposing faces of the printed circuit board 102. These could be ground pins, power pins, or signal pins, e.g., from opposed connectors 104. In one embodiment, the pins 202 are pressfit cage pins from the connectors (see FIG. 8). Plating 206 electrically connects the two pins 202, and can also connect to one or more ground planes, power planes, or signal traces of the printed circuit board 102, depending upon the pin connection requirements for a given design.

FIG. 7C is a cross-section view of the printed circuit board 102, showing a variation of the staggered via 706 of FIG. 7B. In this embodiment, one portion of the via 708 is drilled and has plating 206 to fit a pin 202 inserted from one face of the printed circuit board 102. The other portion of the via 708 has an offset back drilling to a larger diameter, so that the walls of that portion of the via 708 do not contact the pin 202 inserted from the opposed face of the printed circuit board 102. In a further variation, the portion of the via 708 that does not contact the pin 202 is produced by a larger diameter back drilling but without an offset. The larger diameter back drilling, for any of these versions, can be performed after the plating 206 is deposited, so that there is no electrical conductivity available to that pin 202 in the via 708. Or, in a still further variation, plating 206 could be applied after the larger diameter back drilling. As an example of how this could be used with various connectors 104, the larger diameter back drilling could be made at alternating locations on top and bottom of the printed circuit board 102, so that alternating ground cage pins (see FIG. 8) of each of two opposed connectors 104 do not connect to ground of the printed circuit board 102, while the remaining other, alternating ground cage pins of each of the two opposed connectors 104 do connect to ground of the printed circuit board 102.

FIG. 7D is a cross-section view of the printed circuit board, showing a further variation of the staggered via of FIG. 7B. in this version, the second back drilling 708 is of an even larger diameter than in FIG. 7C. Various offsets could be tried, producing various amounts of stagger for the walls in the staggered via 710.

FIG. 8 is a perspective view of a QSFP (quad small form factor pluggable) connector 802, suitable for use in embodiments of the present disclosure. Four cables 106 (one for each channel) are inserted through a 2×2 arrangement of openings at one end of the connector 802. A variety of pins project from one face of the connector 802. Cage pins 806 project along sides of the cage 804 (i.e., box, case, or housing) of the connector 802. These are grounded, pressfit pins in some embodiments. Plastic alignment pins 808 project from two locations along the sides of the cage 804 of the connector 802. In some embodiments, the plastic alignment pins 808 are deleted, removed, or otherwise not present on the QSFP connector 802, so that a thinner thickness of printed circuit board 102 can be used than would otherwise be possible with the plastic alignment pins 802 intact. This solves a problem arising from plastic alignment pins 802 from opposed connectors 802 otherwise interfering in such a thin printed circuit board 102. Signal and power pins 810 project from a signal and power pin region 812 of the connector 802. Generally, the cage pins 806 are of a larger width than the signal and power pins 810, and have correspondingly larger diameter holes for the vias in the printed circuit board 102 as compared to vias for signals. Sixteen QSFP connectors 802 can be mounted to the printed circuit board 102 as shown in FIG. 1A, eight to one face, and eight more to an opposed face of the printed circuit board 102, using various combinations of embodiments of vias as shown and described herein, and variations thereof.

FIG. 9 is a flow diagram of a method for making a printed circuit board, which can produce the embodiments shown in FIGS. 4 and 6 and variations thereof. Drilling can be done with drill bits or lasers, etc., and should be dimensioned as to width, depth, and arrangement so that, with plating, the vias so produced fit the desired connectors and pins. In an action 902, holes are drilled, to a first diameter, through the printed circuit board. In an action 904, the holes are back drilled to a second diameter and first controlled depth, from a first face of the printed circuit board. In an action 906, the holes are plated. In an action 908, the holes are back drilled to a third diameter and second controlled depth, from a second face of the printed circuit board. The controlled depths do not need to be identical, but could be for symmetry. Various possibilities and reasons for selecting specific widths for the various drillings and controlled depths for the back drillings are discussed with reference to FIG. 4.

Drilling the holes to the first diameter all the way through the printed circuit board, in the action 402, has advantages for alignment for each of the first and second back drilling operations. However, variations of the method could be performed in which the action 402 drills only part way through the printed circuit board, and one of the back drillings is aligned using markings, projections, other holes, or other features on the printed circuit board rather than aligning to a hole drilled all the way through the printed circuit board.

The method can also be performed by repeating with the first and second faces of the printed circuit board swapped, so that the back drilled dual-diameter vias are produced in opposing orientations, as depicted in FIG. 4. The method can be performed by omitting the second back drilling operation, the action 408, so that dual-diameter vias as depicted in FIG. 3 are produced.

Detailed illustrative embodiments are disclosed herein. However, specific functional details disclosed herein are merely representative for purposes of describing embodiments. Embodiments may, however, be embodied in many alternate forms and should not be construed as limited to only the embodiments set forth herein. It should be appreciated that descriptions of direction and orientation are for convenience of interpretation, and the apparatus is not limited as to orientation with respect to gravity. In other words, the apparatus could be mounted upside down, right side up, diagonally, vertically, horizontally, etc., and the descriptions of direction and orientation are relative to portions of the apparatus itself, and not absolute.

It should be understood that although the terms first, second, etc. may be used herein to describe various steps or calculations, these steps or calculations should not be limited by these terms. These terms are only used to distinguish one step or calculation from another. For example, a first calculation could be termed a second calculation, and, similarly, a second step could be termed a first step, without departing from the scope of this disclosure. As used herein, the term “and/or” and the “/” symbol includes any and all combinations of one or more of the associated listed items.

As used herein, the singular forms “a”, “an” and “the” are intended to include the plural forms as well, unless the context clearly indicates otherwise. It will be further understood that the terms “comprises”, “comprising”, “includes”, and/or “including”, when used herein, specify the presence of stated features, integers, steps, operations, elements, and/or components, but do not preclude the presence or addition of one or more other features, integers, steps, operations, elements, components, and/or groups thereof. Therefore, the terminology used herein is for the purpose of describing particular embodiments only and is not intended to be limiting.

It should also be noted that in some alternative implementations, the functions/acts noted may occur out of the order noted in the figures. For example, two figures shown in succession may in fact be executed substantially concurrently or may sometimes be executed in the reverse order, depending upon the functionality/acts involved.

Although the method operations were described in a specific order, it should be understood that other operations may be performed in between described operations, described operations may be adjusted so that they occur at slightly different times or the described operations may be distributed in a system which allows the occurrence of the processing operations at various intervals associated with the processing.

Various units, circuits, or other components may be described or claimed as “configured to” perform a task or tasks. In such contexts, the phrase “configured to” is used to connote structure by indicating that the units/circuits/components include structure (e.g., circuitry or mechanical features) that performs the task or tasks during operation. As such, the unit/circuit/component can be said to be configured to perform the task even when the specified unit/circuit/component is not currently operational (e.g., is not on). The units/circuits/components used with the “configured to” language include hardware—for example, circuits, memory storing program instructions executable to implement the operation, etc. Reciting that a unit/circuit/component is “configured to” perform one or more tasks is expressly intended not to invoke 35 U.S.C. 112, sixth paragraph, for that unit/circuit/component. Additionally, “configured to” can include generic structure (e.g., generic circuitry) that is manipulated by software and/or firmware (e.g., an FPGA or a general-purpose processor executing software) to operate in manner that is capable of performing the task(s) at issue. “Configured to” may also include adapting a manufacturing process (e.g., a semiconductor fabrication facility) to fabricate devices (e.g., integrated circuits or manufactured articles) that are adapted to implement or perform one or more tasks, or designing an article or apparatus to have certain features or capabilities.

The foregoing description, for the purpose of explanation, has been described with reference to specific embodiments. However, the illustrative discussions above are not intended to be exhaustive or to limit the invention to the precise forms disclosed. Many modifications and variations are possible in view of the above teachings. The embodiments were chosen and described in order to best explain the principles of the embodiments and its practical applications, to thereby enable others skilled in the art to best utilize the embodiments and various modifications as may be suited to the particular use contemplated. Accordingly, the present embodiments are to be considered as illustrative and not restrictive, and the invention is not to be limited to the details given herein, but may be modified within the scope and equivalents of the appended claims.

1-14. (canceled)

15. A printed circuit board with a first face and opposing second face, comprising:
a plurality of staggered vias, extending through the printed circuit board, and having a first section staggered relative to a second section;
each of the plurality of staggered vias dimensioned to receive a first pin from a first connector, through the first face of the printed circuit board; and
each of the plurality of staggered vias dimensioned to receive a second pin from a second connector, through the second face of the printed circuit board, with pins of the second connector offset relative to pins of the first connector.

16. The printed circuit board of claim 15, wherein each of the plurality of staggered vias is formed by offsetting drilling from the first face, for the first section, relative to drilling from the second face, for the second section.

17. The printed circuit board of claim 15, wherein each of the plurality of staggered vias is formed without an initial straight through hole.

18-19. (canceled)

20. The printed circuit board of claim 15, wherein at least one of the plurality of staggered vias has the first section equal in width to the second section and offset from the second section.

21-26. (canceled)

27. The printed circuit board of claim 15, further comprising each of the plurality of staggered vias having plating that electrically connects the first pin and the second pin.

28. The printed circuit board of claim 15, wherein each of the plurality of staggered vias is produced by symmetric depth offset back drilling.

29. The printed circuit board of claim 15, further comprising:
each of the plurality of staggered vias having plating so as to connect the first pin and the second pin to each other and to a ground plane, a power plane or a signal trace of the printed circuit board.

30. A printed circuit board and connector arrangement, comprising:
a printed circuit board having a first face and opposed second face;
a first connector having a first plurality of pins;
a second connector having a second plurality of pins; and
the first connector assembled to the first face of the printed circuit board, and the second connector assembled to the second face of the printed circuit board, with the first plurality of pins offset from the second plurality of pins, and the first plurality of pins connected to the second plurality of pins through a plurality of staggered vias of the printed circuit board, each of the plurality of staggered vias having a first section staggered relative to a second section.

31. The printed circuit board and connector arrangement of claim 30, wherein at least one of the plurality of staggered vias has a first controlled depth drilling from the first face of the printed circuit board and a second controlled depth drilling of equal depth to the first controlled depth drilling, from the second face of the printed circuit board.

32. The printed circuit board and connector arrangement of claim 30, wherein at least one of the plurality of staggered vias has a first controlled depth drilling from the first face of the printed circuit board and a second controlled depth drilling of unequal depth to the first controlled depth drilling, from the second face of the printed circuit board.

33. The printed circuit board and connector arrangement of claim 30, wherein at least one of the plurality of staggered vias has a first drilling from the first face of the printed circuit board and a second drilling from the second face of the printed circuit board, and each of the first and second drillings is of greater than minimum diameter for drillings for the printed circuit board.

34. The printed circuit board and connector arrangement of claim 30, further comprising:
plating connecting at least one of the plurality of staggered vias and one or more ground planes, one or more power planes or one or more signal traces of the printed circuit board.
